(19) United States
(12) Patent Application Publication
(10) Pub. No.: US 2008/0117696 A1
(43) Pub. Date: May 22, 2008

(54) METHOD FOR REPAIRING DEFECTS IN MEMORY AND RELATED MEMORY SYSTEM

(76) Inventors: Chuan-Jen Chang, Hsinchu County (TW); Yen-Ping Chou, Taipei County (TW); Wei-Li Liu, Taipei County (TW)

Correspondence Address: NORTH AMERICA INTELLECTUAL PROPERTY CORPORATION, P.O. BOX 506, MERRIFIELD, VA, 22116, US

(21) Appl. No.: 11/751,046

(22) Filed: May 21, 2007

(30) Foreign Application Priority Data
Nov. 20, 2006 (TW) 095142805

(51) Int. Cl. G11C 29/00

(52) U.S. Cl. 365/200

(57) ABSTRACT

A method for repairing defects in a memory is disclosed. The method includes: performing a defect test on the memory to obtain at least one defect address of the memory, storing the at least one defect address into a storage media, storing the at least one defect address stored in the storage media into a storage module of the memory, determining whether a target address matches any of the at least one defect address after an access request pointing to the target address of the memory is received, and accessing a redundant cell of a memory cell directed by the target address in response to the access request.

### BACKGROUND OF THE INVENTION

1. Field of the Invention

The present invention relates to a method for repairing defects in a memory, and more particularly, to a soft repair method and related memory system for repairing defects in the memory.

2. Description of the Prior Art

With the development of miniaturized memory elements and the complexity of fabrication processes, the memory elements are easily affected by various defects. Manufacturers have to adopt some particular repair methods for solving problems caused by the various defects in the memory elements. For example, when producing the memory elements, the manufacturers also produce some fuses and redundant circuits (e.g. redundant rows and redundant columns) in the memory elements. After detecting a defect cell in the memory element, the manufacturers connect the redundant cell to an address linking to the defect cell by utilizing the fuses, and the problem resulting from the defect cell can be solved.

Currently, fuses and e-fuses are mostly applied into repair methods for solving the problems caused by the various defects, and both of them relate to hard repair methods. That is, the address originally linking to the defect cell is permanently connected to the redundant cell after the above-mentioned hard repair method relating to the fuses and e-fuses is completed. Ideally, the problems caused by the defects in the memory element should be permanently solved. However, the above-mentioned hard repair method causes a risk of damaging the memory elements. Even though the hard repair method is completed, no additional defect occurring in the memory elements is not guaranteed. If other defects occur in the memory elements after the memory elements are sold, these defects may therefore cause the memory element to operate erroneously or bring about another problem.

### SUMMARY OF THE INVENTION

According to an embodiment of the claimed invention, a method for repairing defects in a memory is disclosed. The method comprises: performing a defect test on the memory to obtain at least one defect address of the memory; storing the at least one defect address into a storage media; storing the at least one defect address stored in the storage media into a storage module of the memory; determining whether a target address matches any of the at least one defect address after an access request pointing to the target address of the memory is received; and accessing a redundant cell of a memory cell directed by the target address in response to the access request after the target address matches one of the at least one defect address.

According to an embodiment of the claimed invention, a memory system is further disclosed. The memory system comprises a memory, a storage media, and a memory controller. The memory controller is coupled to the memory and the storage media, and is utilized for performing a defect test on the memory to obtain at least one defect address of the memory, storing the at least one defect address into a storage media, and storing the at least one defect address stored in the storage media into a storage module of the memory.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a simplified diagram of a memory system according to an embodiment of the present invention.

FIG. 2 is a flowchart illustrating an example of repairing defects in the memory by utilizing the memory system shown in FIG. 2.

### DETAILED DESCRIPTION

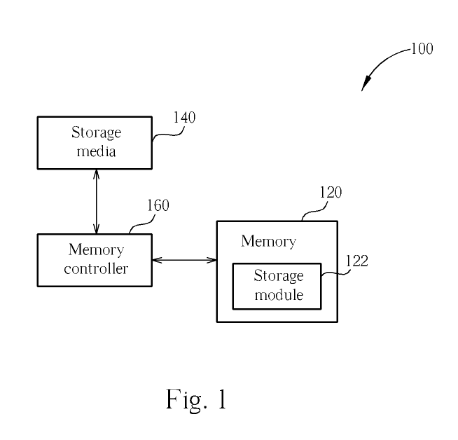

Please refer to FIG. 1. FIG. 1 is a simplified diagram of a memory system 100 according to an embodiment of the present invention. As shown in FIG. 1, the memory system 100 comprises a memory 120, a storage media 140, and a memory controller 160. The memory 120 comprises a storage module 122, and the storage module 122 can be implemented with a register or a latch built within the memory 120. The storage media 140 can be a register, a latch or other storage media built within the memory controller 160 (or outside of the memory controller 160).

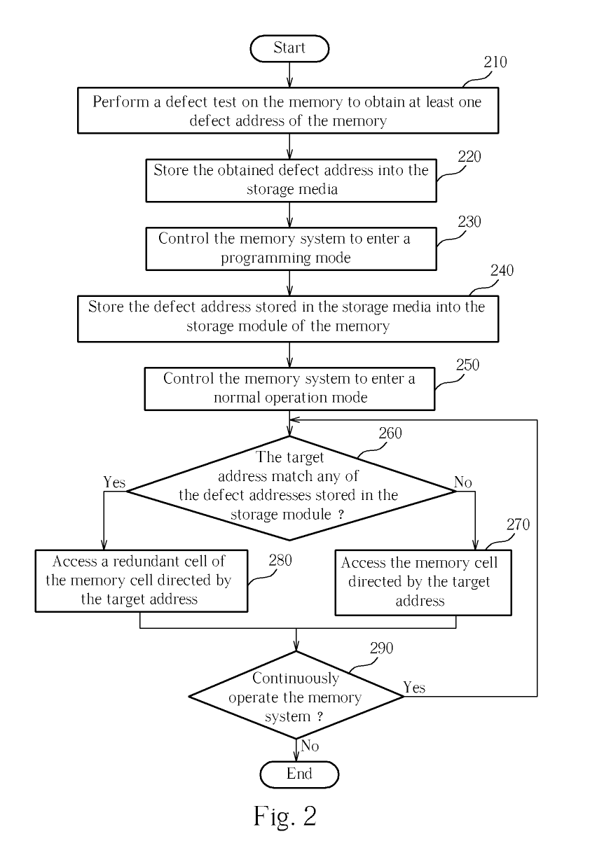

Please refer to FIG. 2. FIG. 2 is a flowchart illustrating an example of repairing defects in the memory 120 by utilizing the memory system 100 shown in FIG. 1. The description is detailed as follows:

Step 210: the memory controller 160 performs a defect test on the memory 120 to obtain at least one defect address of the memory 120.

Step 220: the memory controller 160 stores the obtained defect address into the storage media 140.

Step 230: the memory controller 160 controls the memory system 100 to enter a programming mode. For example, the memory controller 160 can control the memory system 100 to enter the programming mode by utilizing a specific programming mode entry sequence. The specific programming mode entry sequence can be a specific command, address, or input combination being transmitted into the memory 120.

Step 240: in the programming mode, the memory controller 160 stores the defect address stored in the storage media 140 into the storage module 122 of the memory 120 by issuing a specific command (e.g. a row strobe or column strobe).

Step 250: the memory controller 160 controls the memory system 100 to enter a normal operation mode. For instance, the memory controller 160 can control the memory system 100 to enter the normal operation mode by utilizing a specific normal operation mode entry sequence. The specific normal operation mode entry sequence can be a specific command, address, or input combination being transmitted into the memory 120.

Step 260: after an access request (e.g. a read request or write request) pointing to a target address of the memory 120 is received from the memory controller 160, the memory 120 determines whether the target address matches any of the defect addresses stored in the storage module 122. If the target address does not match any of the defect addresses stored in the storage module 122, go to Step 270. Otherwise, if the target address matches one of the defect addresses stored in the storage module 122, go to Step 280.

Step 270: since the memory 120 determines that the target address does not match any of the defect addresses stored in the storage module 122, a memory cell directed by the target address is not a defect cell. The memory 120 can therefore access the memory cell directed by the target address in response to the access request.

Step 280: since the memory 120 determines that the target address matches one of the defect addresses stored in the storage module 122, the memory cell directed by the target address is a defect cell. In response to the access request, the memory 120 accesses a redundant cell of the memory cell directed by the target address instead of accessing the memory cell. The above-mentioned redundant cell can be located at a redundant row or redundant column in the memory 120.

Step 290: if the memory system 100 determines to operate continuously, go to Step 260; otherwise, the procedure shown in this flowchart is completed.

In the above-mentioned embodiment, the disclosed method for repairing defects in the memory 120 relates to a soft repair method for the memory 120. After the power supply is enabled each time, Steps 210-250 can be executed before employing the memory system 100. In Steps 260-290, the problem caused by the defects in the memory 120 can be solved temporarily. An advantage of the soft repair method is that it is not necessary to cause a physical change to the memory 120. Therefore, the risk of causing damage to the memory 120 can be reduced. Even though an additional defect cell occurs in the memory 120, the problem caused by the original and additional defect cells in the memory 120 can be solved by executing Steps 210-250 again.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for repairing defects in a memory, comprising:
performing a defect test on the memory to obtain at least one defect address of the memory;
storing the at least one defect address into a storage media;
storing the at least one defect address stored in the storage media into a storage module of the memory;
determining whether a target address matches any of the at least one defect address after an access request pointing to the target address of the memory is received; and
accessing a redundant cell of a memory cell directed by the target address in response to the access request after the target address matches one of the at least one defect address.

2. The method of claim 1, further comprising:
accessing the memory cell directed by the target address in response to the access request if the target address does not match any of the at least one defect address.

3. The method of claim 1, wherein the step of storing the at least one defect address stored in the storage media into the storage module of the memory:
controlling the memory to enter a programming mode; and
storing the at least one defect address stored in the storage media into the storage module of the memory in the programming mode.

4. The method of claim 3, further comprising:
controlling the memory to enter a normal operation mode after storing the at least one defect address stored in the storage media into the storage module.

5. The method of claim 1, wherein the storage module is a register built in the memory.

6. The method of claim 1, wherein the storage module is a latch built in the memory.

7. The method of claim 1, wherein the storage media is outside of the memory.

8. The method of claim 1, wherein the redundant cell is located at a redundant row of the memory.

9. The method of claim 1, wherein the redundant cell is located at a redundant column of the memory.

10. A memory system, comprising:
a memory;
a storage media; and
a memory controller, coupled to the memory and the storage media, for performing a defect test on the memory to obtain at least one defect address of the memory, storing the at least one defect address into a storage media, and storing the at least one defect address stored in the storage media into a storage module of the memory.

11. The memory system of claim 10, wherein the memory determines whether a target address matches any of the at least one defect address after the memory receives an access request pointing to the target address from the memory controller.

12. The memory system of claim 11, wherein the memory accesses a redundant cell of a memory cell directed by the target address in response to the access request after the target address matches one of the at least one defect address.

13. The memory system of claim 12, wherein the redundant cell is located at a redundant row of the memory.

14. The memory system of claim 12, wherein the redundant cell is located at a redundant column of the memory.

15. The memory system of claim 11, wherein the memory accesses a memory cell directed by the target address in response to the access request if the target address does not match any of the at least one defect address.

16. The memory system of claim 10, wherein the memory controller stores the at least one defect address stored in the storage media into the storage module of the memory after the memory controller controls the memory to enter a programming mode.

17. The memory system of claim 16, wherein the memory controller controls the memory to enter a normal operation mode after the at least one defect address stored in the storage media is stored into the storage module.

18. The memory system of claim 10, wherein the storage module is a register built in the memory.

19. The memory system of claim 10, wherein the storage module is a latch built in the memory.

20. The memory system of claim 10, wherein the storage media is outside of the memory.
